(19) United States
(12) Patent Application Publication
(10) Pub. No.: US 2010/0244066 A1
(43) Pub. Date: Sep. 30, 2010

(54) RED LIGHT FLUORESCENT MATERIAL AND MANUFACTURING METHOD THEREOF, AND WHITE LIGHT LUMINESCENT DEVICE

(75) Inventors: Chuang-Hung Chiu, Hsinchu County (TW); Teng-Ming Chen, Hsinchu City (TW); Chi-Neng Mo, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taoyuan (TW)

(21) Appl. No.: 12/469,706

(22) Filed: May 21, 2009

(30) Foreign Application Priority Data
Mar. 27, 2009 (TW) 98110232

(51) Int. Cl. H01L 33/00; C09K 11/68

(52) U.S. Cl. 257/98; 252/301.5; 252/301.4 R; 257/E33.061

(57) ABSTRACT

A red-light-emitting fluorescent material, suitable for being excited by a first light to emit red light, is provided. The red-light-emitting fluorescent material is characterized in the chemical formula (1):

A₃B₂C₃(MO₄)₈:Eu³⁺ (1)
wherein, A represents Li, Na, K, Rb, Cs or Ag; B represents Mg, Ca, Sr or Ba; C represents Y, Gd or La; M represents Mo, W or combination of Mo and W (MoₓW₍₁₋ₓ₎). The red-light-emitting fluorescent material has high luminance and good color purity. In addition, since the composition of the red-light-emitting fluorescent material is oxide, the red-light-emitting fluorescent material has advantages of good chemical stability and long lifetime.

### CROSS-REFERENCE TO RELATED APPLICATION

This application claims the priority benefit of Taiwan application serial no. 98110232, filed Mar. 27, 2009. The entirety of the above-mentioned patent application is hereby incorporated by reference herein and made a part of specification.

### BACKGROUND OF THE INVENTION

1. Field of the Invention

The present invention generally relates to a red-light-emitting fluorescent material and the manufacturing method thereof, and a white light luminescent device using the red-light-emitting fluorescent material, and more particularly, to a red-light-emitting fluorescent material with high color purity, high luminance and good chemical stability, the manufacturing method of the above-mentioned red-light-emitting fluorescent material and the white light luminescent device using the red-light-emitting fluorescent material.

2. Description of Related Art

In recent years, due to the flourishing green technology, a white light emitting diode (white LED) with the advantages of energy-saving, small size, low driving voltage and mercury-free has been widely used in backlight modules of flat display and common lighting. In order to promote the light-emitting performance of white LED, the research of fluorescent material plays a significant role. And, many novel fluorescent materials have been provided one after another.

U.S. Pat. No. 5,998,925 discloses a white light luminescent device, which mainly adopts yttrium aluminium garnet (YAG) fluorescent powder doped with cesium (Y₃Al₅O₁₂:Ce³⁺, YAG:Ce) to convert blue light emitted from blue LED into yellow light, followed by mixing the blue light with the yellow light so as to produce white light. However, the white light produced by the blue LED and the YAG fluorescent powder doped with cesium always has a problem of high color temperature. In particular, with an increasing operation current, the problem of high color temperature gets more seriously. In addition, the white light produced in such way, the optical spectrum thereof does not contain red wavelength component, so that the color render index (CRI) of the white light is about 80 only and the illumination light source employing the above-mentioned white light luminescent device encounters insufficient color rendering problem. As a result, for example, an object irradiated by the above-mentioned white light appears weak orange color.

The above-mentioned problems can be solved by adding the red wavelength component in the optical spectrum of white light. In U.S. Pat. No. 6,580,097, a blue LED in coordination with a dual phosphor composition system including both red-light-emitting fluorescent material and green-light-emitting fluorescent material is used to produce white light. The dual phosphor composition system includes red-light-emitting fluorescent powder containing sulphur (Y₂O₂S:Eu³⁺, Bi³⁺; SrS:Eu²⁺; SrY₂S₄:Eu², or CaLa₂S₄:Ce³⁺) and green-light-emitting fluorescent material doped with rare-earth ions, and the white light produced by the blue LED in coordination with the above-mentioned dual phosphor composition system gains better color rendering.

Although, using the above-mentioned blue LED and dual phosphor composition system can produce white light without the problems of color temperature and color rendering, however, the employed fluorescent powder in the composition contains sulfide which is easy to react with the moisture in air and results in poor chemical stability of the dual phosphor composition system. In addition, under a long time irradiation by ultraviolet radiation, the dual phosphor composition system is likely decayed resulting in a shorter lifetime. Moreover, due to the poor thermal stability of the sulfide, the sulfide-based fluorescent powder has many application limits.

### SUMMARY OF THE INVENTION

Accordingly, the present invention is directed to a red-light-emitting fluorescent material able to provide light with intensive luminance and high color purity.

The present invention is also directed to a manufacturing method of red-light-emitting fluorescent material, by which a red-light-emitting fluorescent material with good chemical stability can be obtained in a lower sintering temperature.

The present invention is further directed to a white light luminescent device, which employs the above-mentioned red-light-emitting fluorescent material, and the white light luminescent device has long lifetime and good color rendering.

The present invention provides a red-light-emitting fluorescent material, which is suitable for being excited by a first light to emit a red light. The red-light-emitting fluorescent material has the following feature. The chemical formula of the red-light-emitting fluorescent material is:

A₃B₂C₃(MO₄)₈:Eu³⁺ (1)

In the chemical formula (1), A represents lithium (Li), sodium (Na), potassium (K), rubidium (Rb), cesium (Cs) or silver (Ag); B represents magnesium (Mg), calcium (Ca), strontium (Sr) or Barium (Ba); C represents yttrium (Y), gadolinium (Gd) or lanthanum (La); M represents molybdenum (Mo), tungsten (W) or the combination of Mo and W (MoₓW₍₁₋ₓ₎).

In an embodiment of the present invention, the wavelength ranges of the first light is between 360 nm˜550 nm.

In an embodiment of the present invention, the wavelength ranges of the first light include, wavelength range of near-ultraviolet radiation 394±10 nm, wavelength range of blue light 465±10 nm or wavelength range of yellow-green light 535±10 nm.

In an embodiment of the present invention, the wavelength of the red light includes 614 nm.

In an embodiment of the present invention, in the M expression of combination of Mo and W (MoₓW₍₁₋ₓ₎), x is mole fraction and x is between 0˜1.

In an embodiment of the present invention, the color coordinates of the red light reach (0.66, 0.33).

In an embodiment of the present invention, the relative luminance of the red light is 1.5˜1.8 (cd/m²).

In an embodiment of the present invention, the red-light-emitting fluorescent material is suitable for being used in a white light emitting diode.

The present invention also provides a manufacturing method of red-light-emitting fluorescent material. The manufacturing method of red-light-emitting fluorescent material includes following steps. First, provides a mixture as per chemical dose, wherein the mixture includes a metal carbonate, an alkaline-earth-metal carbonate, a trivalent metal oxide, a rare earth oxide, and a molybdenum trioxide, or a tungsten trioxide or a combination of molybdenum trioxide and tungsten trioxide. Then, mixes up and grinds the mixture. After that, sinters the mixture after being mixed and grinded so as to form the red-light-emitting florescent material.

In an embodiment of the present invention, the manufacturing method of red-light-emitting fluorescent material further includes: providing a halogenated ammonium salt as flux, and the weight percent of the halogenated ammonium salt is 10 wt %.

In an embodiment of the present invention, the time for mixing and grinding the above-mentioned mixture is 30 min.

In an embodiment of the present invention, the sintering temperature of the mixture is 600° C.˜800° C.

In an embodiment of the present invention, the sintering time of the mixture is between 6˜10 hours.

In an embodiment of the present invention, the red-light-emitting fluorescent material has following chemical formula (1):

A₃B₂C₃(MO₄)₈:Eu³⁺ (1)

wherein, A represents Li, Na, K, Rb, Cs or Ag; B represents Mg, Ca, Sr or Ba; C represents Y, Gd or La; M represents Mo, W or combination of Mo and W (MoₓW₍₁₋ₓ₎).

In an embodiment of the present invention, the manufacturing method of red-light-emitting fluorescent material further includes: a characteristics identification step for identifying physical and chemical characteristics of the red-light-emitting florescent material.

In an embodiment of the present invention, the characteristics identification step includes: X-radiation diffraction analysis, photoluminescence (PL) spectroscopic analysis, chromaticity coordinate analysis or ultraviolet radiation-visual light reflection spectrum analysis.

The present invention further provides a white light luminescent device, which includes a light-emitting-diode chip for emitting a first light and a photo-luminescent fluorescence body. The photo-luminescent fluorescence body includes at least the above-mentioned red-light-emitting fluorescent material. The photo-luminescent fluorescence body is excited by the first light to emit a second light, and the first light and the second light are mixed into white light.

In an embodiment of the present invention, the wavelength range of the first light is between 360 nm˜550 nm.

In an embodiment of the present invention, the wavelength range of the first light includes: wavelength range of near-ultraviolet radiation 394±10 nm, wavelength range of blue light 465±10 nm or wavelength range of yellow-green light 535±10 nm.

In an embodiment of the present invention, the photo-luminescent fluorescence body further includes: a yellow-light-emitting fluorescent material, a blue-light-emitting fluorescent material or a green-light-emitting fluorescent material, wherein, the red-light-emitting fluorescent material is suitable for application in coordination with the yellow-light-emitting fluorescent material, a blue-light-emitting fluorescent material, a green-light-emitting fluorescent material and a combination thereof.

Since the red-light-emitting fluorescent material of the present invention adopts a novel chemical structure, the red-light-emitting fluorescent material is able to provide red light with high color purity and intensive luminance. In particular, in the manufacturing method of red-light-emitting fluorescent material of the present invention, the composition of the red-light-emitting fluorescent material is oxide and contains no sulfide with poor chemical stability, so that the red-light-emitting fluorescent material has good chemical stability. In addition, due to the low sintering temperature, energy consumption is low. Moreover, since the white light luminescent device of the present invention employs the above-mentioned red-light-emitting fluorescent material, the white light luminescent device can provide white light with good color rendering and has long lifetime.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic flowchart of the manufacturing method of the red-light-emitting fluorescent material according to an embodiment of the present invention.

FIG. 2 is a graphic of an excited-light optical spectrum of the red-light-emitting fluorescent material according to an embodiment of the present invention, where the excited-light optical spectrums are corresponding to the embodiments 1˜5.

FIG. 3 is a diagram of chromaticity coordinates of the red-light-emitting fluorescent material according to an embodiment of the present invention.

FIG. 4 is a diagram of a white light luminescent device according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The present invention provides a novel red-light-emitting fluorescent material, which has a unique chemical crystal structure and is able to produce red light with high color purity and high luminance. In addition to solve insufficient color rendering in the prior art, the novel red-light-emitting fluorescent material has a structure without sulfide so as to ultimately solve the problem of poor chemical stability. The red-light-emitting fluorescent materials and the manufacturing method thereof, and the white light luminescent device employing the red-light-emitting fluorescent material are depicted in following.

### Red-Light-Emitting Fluorescent Material

The red-light-emitting fluorescent material provided by the present invention is suitable for being excited by a first light to emit a red light. The red-light-emitting fluorescent material has the chemical formula (1),

A₃B₂C₃(MO₄)₈:Eu³⁺ (1)

wherein, A represents lithium (Li), sodium (Na), potassium (K), rubidium (Rb), cesium (Cs) or silver (Ag); B represents magnesium (Mg), calcium (Ca), strontium (Sr) or Barium (Ba); C represents yttrium (Y), gadolinium (Gd) or lanthanum (La); M represents molybdenum (Mo), tungsten (W) or the combination of Mo and W (MoₓW₍₁₋ₓ₎).

It should be noted that in the M expression of combination of Mo and W (MoₓW₍₁₋ₓ₎), x is mole fraction and x is between 0˜1. While a range of wavelength of the first light is between 350 nm˜550 nm. In other words, the red-light-emitting fluorescent material quite suits to be exited by the first light with a waveband from ultraviolet radiation to blue light and wavebands of yellow-green light, so as to emit the red light.

In chemical formula (1), A₃B₂C₃(MO₄)₈ is the primary structure of the red-light-emitting fluorescent material and Eu³⁺ is the trivalent europium ion doped in the primary structure of the red-light-emitting fluorescent material. The red-light-emitting fluorescent material is mainly based on a special MO₄ crystal structure with eight covalent bonds formed by the above-mentioned metal atom A, alkaline-earth metal atom B and rare earth metal atom C, followed by being doped with trivalent europium ions in the special MO₄ crystal structure, so that the red-light-emitting fluorescent material can absorb the energy of the first light and then emit the red light.

The red-light-emitting fluorescent material is excellent to absorb light with special wavelengths. The preferred three absorption wavelength ranges are, wavelengths of near-ultraviolet radiation 394±10 nm, wavelengths of blue light 465±10 nm or wavelengths of yellow-green light 535±10 nm. After absorbing the energy of the light with the special wavelengths, the red-light-emitting fluorescent material releases the absorbed energy in form of red light, and the wavelength of the red light is, for example, 614 nm.

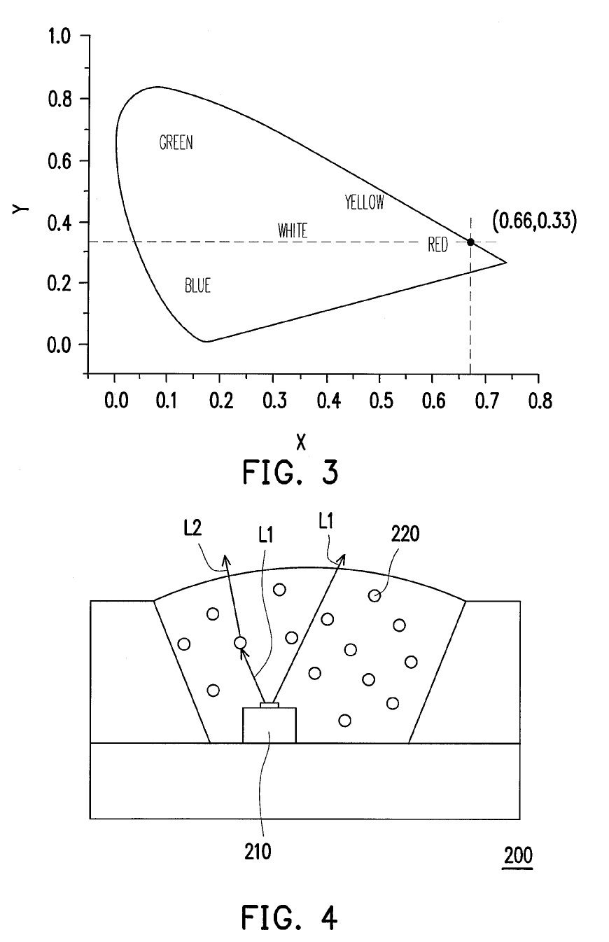

The red light emitted by the red-light-emitting fluorescent material has a color purity reaching a position corresponding to the NTSC color coordinates (0.66, 0.33); that is the color purity of the red light is near to saturated red color (as shown in FIG. 3). In addition, the relative luminance of the red light can reach 1.5˜1.8 (cd/m²) (as shown in Table 1).

Since the red-light-emitting fluorescent material can provide the red light with high luminance and good color purity, the red-light-emitting fluorescent material is quite suitable for being applied in white LEDs.

### Manufacturing Method of Red-Light-Emitting Fluorescent Material

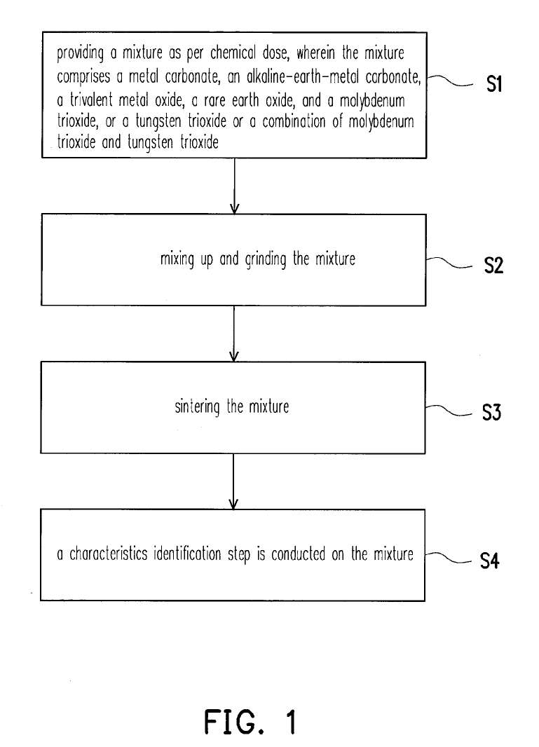

FIG. 1 is a schematic flowchart of the manufacturing method of the red-light-emitting fluorescent material according to an embodiment of the present invention. Referring to FIG. 1, first, in step S1, a mixture is provided as per chemical dose. The mixture includes a metal carbonate, an alkaline-earth-metal carbonate, a trivalent metal oxide, a rare earth oxide, and a molybdenum trioxide, or a tungsten trioxide or a combination of molybdenum trioxide and tungsten trioxide.

Specifically, in the above-mentioned manufacturing method of the red-light-emitting fluorescent material, the composition ratios of all the components in the red-light-emitting fluorescent material are assigned as per the mole fraction displayed by the above-mentioned chemical formula (1), wherein the metal carbonate is, for example, lithium carbonate (Li₂CO₃) the alkaline-earth-metal carbonate is, for example, barium carbonate (BaCO₃), the trivalent metal oxide is, for example, europium oxide (Eu₂O₃), and the rare earth oxide is, for example, gadolinium oxide (Gd₂O₃).

Next, in step S2, the above-mentioned mixture is mixed up, followed by grinding them. In order to mix the mixture more uniformly, in step S2, the time for mixing and grinding thereof is about 30 minute required.

Further, in step S3, the mixture, after being mixed and grinded, are sintered so as to form the red-light-emitting fluorescent material. The sintering procedure can be, for example, putting the above-mentioned uniformly-mixed and grinded mixture in a aluminium oxide crucible, then, putting the aluminium oxide crucible containing the mixture in a high-temperature furnace and sintering the mixture at a temperature between 600° C.˜800° C. for about 6˜10 hours. Finally, the red-light-emitting fluorescent material is obtained.

The obtained red-light-emitting fluorescent material takes oxide form and has the following chemical formula: A₃B₂C₃(MO₄)₈:Eu³⁺, wherein A represents Li, Na, K, Rb, Cs or Ag; B represents Mg, Ca, Sr or Ba; C represents Y, Gd or La; M represents Mo, W or the combination of Mo and W (MoₓW₍₁₋ₓ₎).

In addition, in the sintering step S3, a halogenated ammonium salt with the weight percent 10 wt % can be added and the halogenated ammonium herein serves as a flux to assist the sintering.

Continuing to FIG. 1, as shown in step S4, a characteristic identification step is conducted on the red-light-emitting fluorescent material obtained after the above-mentioned steps S1-S3, and the characteristic identification step is for identifying characteristics of red-light-emitting fluorescent material. The characteristic identification step may include X-radiation diffraction analysis, photoluminescence (PL) spectroscopic analysis, chromaticity coordinate analysis or ultraviolet radiation-visual light reflection spectrum analysis, but not limited by thereof.

It should be noted that in the manufacturing method of red-light-emitting fluorescent material, the major compositions are metal carbonate, alkaline-earth-metal carbonate, trivalent metal oxide, rare earth oxide, and molybdenum trioxide, or tungsten trioxide or a combination of molybdenum trioxide and tungsten trioxide, and the required sintering temperature is 600° C.˜800° C. only. In comparison with the prior art where YAG fluorescent material doped with cesium (the required sintering temperature is 1,500° C.), fluorescent material of silicate and germanium salt family (the required sintering temperature is 1,000° C.˜1,200° C.) and red-light-emitting fluorescent material containing sulphur (the required sintering temperature is 1,100° C.˜1,200° C.) are employed, the manufacturing method of red-light-emitting fluorescent material provided by the present invention is advantageous in lower sintering temperature, less consumption of energy in the fabrication and lower fabrication cost.

Since the red-light-emitting fluorescent material provided by the present invention is composed of oxide and has no sulfide featuring low chemical stability, so that the provided red-light-emitting fluorescent material has excellent chemical stability, which means under a long time irradiation by ultraviolet radiation or a high-temperature environment, the red-light-emitting fluorescent material has longer lifetime and broad applications.

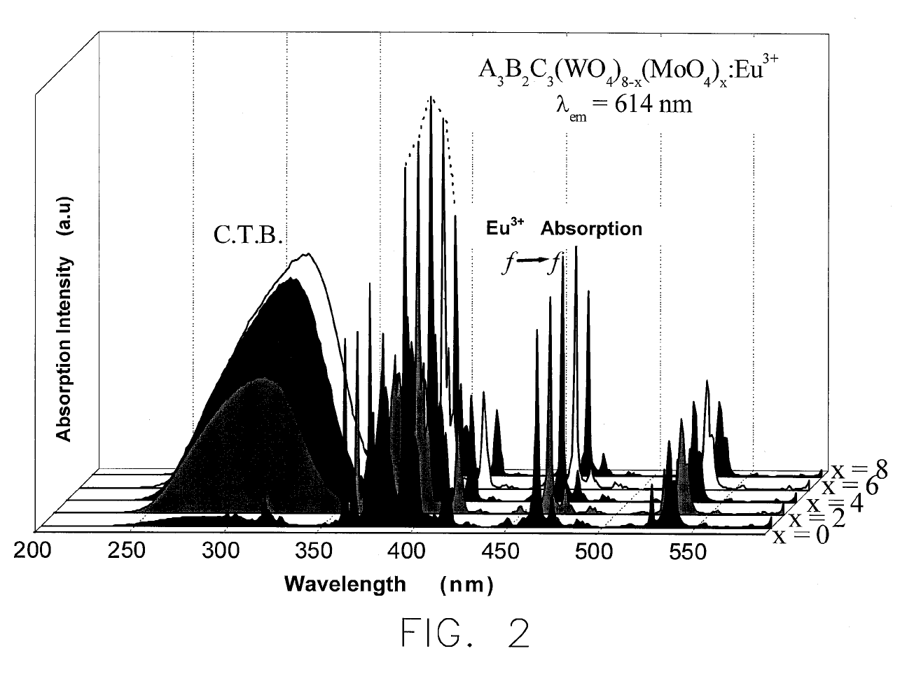

In the following, five sets of the red-light-emitting fluorescent materials fabricated according to the above-mentioned manufacturing method are provided, and results of characteristics identification thereof are depicted in FIGS. 2 and 3. FIG. 2 is a graphic of an excited-light optical spectrum of the red-light-emitting fluorescent material according to an embodiment of the present invention, where the excited-light optical spectrums are corresponding to the embodiments 1˜5. FIG. 3 is a diagram of chromaticity coordinates of the red-light-emitting fluorescent material according to an embodiment of the present invention. In addition, two currently commercial red-light-emitting fluorescent materials are described for comparison for more recognizing the advantages of the present invention.

### The First Embodiment

As shown in FIG. 1, Li₂CO₃, BaCO₃, Eu₂O₃, Gd₂O₃ and tungsten oxide (WO₄) are weighed according to the required chemical doses for forming a mixture. Next, the mixture is grinded for 30 minute and then put in an aluminium oxide crucible. After that, the aluminium oxide crucible is put in a high-temperature furnace for sintering the mixtures at a temperature between 600° C.˜800° C. for about 6˜10 hours. Finally, the red-light-emitting fluorescent material Li₃Ba₂Gd₃(WO₄)₈:Eu³⁺ is obtained.

Then, an ultraviolet radiation-visual light reflection spectrum analysis, a PL spectroscopic analysis and chromaticity coordinate analysis are conducted on Li₃Ba₂Gd₃(WO₄)₈:Eu³. The result of the PL spectroscopic analysis is shown in FIG. 2 where a plurality of absorption peaks of the red-light-emitting fluorescent material (Li₃Ba₂Gd₃(WO₄)₈:Eu³⁺) are given. The result of the fluorescent characteristic analysis is shown in Table 1 which includes the emission peak with wavelength 614 nm of the red-light-emitting fluorescent material (Li₃Ba₂Gd₃(WO₄)₈:Eu³⁺) and the relative luminance thereof. The result of the chromaticity coordinate analysis is shown in FIG. 3 where the chromaticity coordinates of the red light emitted by the red-light-emitting fluorescent material (Li₃Ba₂Gd₃(WO₄)₈:Eu³⁺) can be found.

Specifically, the above-mentioned PL spectroscopic analysis can be conducted by using, for example, Spex Fluorolog-3 spectrofluorometer (Instruments S.A., Edison, N.J., U.S.A.) so as to provide first light with different wavelengths (not shown). The wavelength range of the first light covers 360 nm˜550 nm. After that, the first light generated by the spectrofluorometer passes through the red-light-emitting fluorescent material, and then, a photomultiplier, for example, photomultiplier Hamamatsu Photonics R928, is used to measure the intensity of the absorbed first light or the intensity of the second light emitted by the red-light-emitting fluorescent material. The chromaticity coordinates are measured by a color analyzer, for example, analyzer Laiko DT-100.

Referring to FIG. 2, in the excited-light optical spectrum of the red-light-emitting fluorescent material (Li₃Ba₂Gd₃(WO₄)₈:Eu³⁺) in the first embodiment, the absorption peak appears at x=0. In the excited-light optical spectrum of the first embodiment, the absorption intensities are noticeable at the near-ultraviolet radiation wavelengths 394±10 nm, the blue light wavelengths 465±10 nm and the yellow-green light wavelengths 535±10 nm, especially the most noticeable absorption intensity appears at the ultraviolet radiation wavelength 394 nm. The other absorption peaks between 250 nm˜350 nm are caused mainly by charge transfer band (C.T.B).

After absorbing the energies of the above-mentioned wavelengths, the red-light-emitting fluorescent material emits red light with wavelength 614 nm. Referring to FIG. 3, the color coordinates of the red light emitted by the red-light-emitting fluorescent material can reach (0.66, 0.33) on the NTSC color coordinate system, i.e., the color purity of the red light is near to saturated red color.

### The Second Embodiment

Similarly to the first embodiment, in the second embodiment, by using the manufacturing method described in FIG. 1, Li₂CO₃, BaCO₃, Eu₂O₃,Gd₂O₃,WO₄ and (molybdenum oxide)Mo₂O₃ are weighed according to the required chemical doses to form a mixture. Next, after grinding and sintering the mixture, the red-light-emitting fluorescent material Li₃Ba₂Gd₃(WO₄)₆(MoO₄)₂:Eu³⁺ is obtained.

In the same way, the characteristics identification step is conducted on the red-light-emitting fluorescent material of the second embodiment, and the results are shown in FIGS. 2 and 3. The excited-light optical spectrum of the red-light-emitting fluorescent material (Li₃Ba₂Gd₃(WO₄)₆(MoO₄)₂) in the second embodiment is displayed at x=2.

In the second embodiment, the mole fraction of metal molybdenum salt over metal tungsten salt is 2:6. The optical spectrum of the red-light-emitting fluorescent material in the second embodiment is similar to that in the first embodiment except the peak intensities are somehow different, which is omitted to describe.

### The Third Embodiment

Similarly to the manufacturing method in the second embodiment, the red-light-emitting fluorescent material Li₃Ba₂Gd₃(WO₄)₄(MoO₄)₄:Eu³⁺ can be obtained in the third embodiment. In the same way, the characteristics identification step is conducted on the red-light-emitting fluorescent material of the third embodiment, and the results are shown in FIGS. 2 and 3. The excited-light optical spectrum of the red-light-emitting fluorescent material (Li₃Ba₂Gd₃(WO₄)₄(MoO₄)₄:Eu³⁺) in the third embodiment is displayed at x=4.

In the third embodiment, the mole fraction of metal molybdenum salt over metal tungsten salt is 4:4. The optical spectrum of the red-light-emitting fluorescent material in the third embodiment is similar to that in the first and second embodiments except the peak intensities are somehow different. In particular, in the excited-light optical spectrum of FIG. 2, the intensity of the material (Li₃Ba₂Gd₃(WO₄)₄(MoO₄)₄:Eu³⁺) in the third embodiment is the maximum one.

### The Fourth Embodiment

Similarly to the manufacturing method in the second embodiment, the red-light-emitting fluorescent material Li₃Ba₂Gd₃(WO₄)₂(MoO₄)₆:Eu³⁺ can be obtained in the fourth embodiment. In the same way, the characteristics identification step is conducted on the red-light-emitting fluorescent material of the fourth embodiment, and the results are shown in FIGS. 2 and 3. The excited-light optical spectrum of the red-light-emitting fluorescent material (Li₃Ba₂Gd₃(WO₄)₂(MoO₄)₆:Eu³⁺) in the third embodiment is displayed at x=6.

In the fourth embodiment, the mole fraction of metal molybdenum salt over metal tungsten salt is 6:2. The optical spectrum of the red-light-emitting fluorescent material in the fourth embodiment is similar to that in the first, second and third embodiments except the peak intensities are somehow different, which is omitted to describe.

### The Fifth Embodiment

Similarly to the fabrication method in the first embodiment, by using the manufacturing method described in FIG. 1, Li₂CO₃, BaCO₃, Eu₂O₃,Gd₂O₃ and Mo₂O₃ are weighed according to the required chemical doses to form a mixture. Next, after grinding and sintering the mixture, the red-light-emitting fluorescent material Li₃Ba₂Gd₃(MoO₄)₈: Eu³⁺ is obtained. In the same way, the characteristics identification step is conducted on the red-light-emitting fluorescent material of the fifth embodiment, and the results are shown in FIG. 2 and Table 1. The excited-light optical spectrum of the red-light-emitting fluorescent material (Li₃Ba₂Gd₃(MoO₄)₈:Eu³⁺) in the fifth embodiment is displayed at x=8.

The difference of the fifth embodiment from the first embodiment rests in the tungsten trioxide is entirely replaced by molybdenum trioxide. The optical spectrum of the red-light-emitting fluorescent material in the fifth embodiment is similar to that in the first, second, third and fourth embodiments except the peak intensities are somehow different, which is omitted to describe.

It can be seen from the above-mentioned analysis results that the noticeable absorption intensities of the red-light-emitting fluorescent materials for the fifth until fifth embodiments of the present invention are at the near-ultraviolet radiation wavelengths 394±10 nm, the blue light wavelengths 465±10 nm and the yellow-green light wavelengths 535±10 nm. Especially, the most noticeable absorption intensity appears at the ultraviolet radiation wavelength 394 nm, and the red-light-emitting fluorescent material can emit red light with wavelength 614 nm.

In short, the red-light-emitting fluorescent material can provide red light with high color purity, high luminance and good chemical stability. To verify the conclusion, a comparison of the red-light-emitting fluorescent material of the first˜third embodiments with the commercial red-light-emitting fluorescent materials (the reference example 1 and reference example 2) is conducted. The measurements are conducted on the materials of the first˜fifth embodiments and the materials of the reference examples 1 and 2 by using the instruments mentioned in the first embodiment under the same conditions, and the results are shown in Table 1.

TABLE 1

| | | chromaticity | relative |
|---|---|---|---|
| | red-light-emitting fluorescent | coordinates | luminance |
| | materials | (x, y) | (a.u.) |
| Embodiment | Li₃Ba₂Gd₃(WO₄)₈:Eu³⁺ | (0.66, 0.33) | 1.6 |
| 1 | | | |
| Embodiment | Li₃Ba₂Gd₃(WO₄)₆(MO₄)₂:Eu³⁺ | (0.66, 0.33) | 1.7 |
| 2 | | | |
| Embodiment | Li₃Ba₂Gd₃(WO₄)₄(MO₄)₄:Eu³⁺ | (0.66, 0.33) | 1.8 |
| 3 | | | |
| Embodiment | Li₃Ba₂Gd₃(WO₄)₂(MO₄)₆:Eu³⁺ | (0.66, 0.33) | 1.7 |
| 4 | | | |
| Embodiment | Li₃Ba₂Gd₃(MoO₄)₈:Eu³⁺ | (0.66, 0.33) | 1.5 |
| 5 | | | |
| Reference | Y₂O₂S:Eu³⁺ | (0.66, 0.33) | 1.0 |
| example 1 | | | |
| Reference | La₂O₂S:Eu³⁺ | (0.67, 0.32) | 1.3 |
| example 2 | | | |

Referring to Table 1, the “Embodiments 1˜5” mean the red-light-emitting fluorescent materials of the first˜fifth embodiments. The “Reference example 1” means the commercial red-light-emitting fluorescent material Y₂O₂S:Eu³, for example, Kasei Optonix P22-RE3. The “Reference example 2” means the commercial red-light-emitting fluorescent material La₂O₂S:Eu³⁺, for example, Kasei Optonix KX-681B.

It can be seen in Table 1 that the chromaticity coordinates of the “embodiments 1˜3” are the same as that of the “reference example 1”, both are (0.66, 0.33). In other words, the red light color purity of the red-light-emitting fluorescent material of the first third embodiments is the same as that of the commercial red-light-emitting fluorescent materials and is near to the pure red (0.67, 0.33) defined by the NTSC.

Notice that, the relative luminance of “embodiments 1˜5” is greater than that of “reference examples 1 and 2”. In particular, in the third embodiment, when the mole fraction of tungsten over molybdenum is 4:4, the relative luminance takes the highest value of 1.8 (cd/m²) in Table 1. Among all the items in Table 1, the comparison result suggests the red light emitted by the red-light-emitting fluorescent materials of the present invention not only has good color purity, but also has a relative luminance higher than that of the currently commercial ones.

### White Light Luminescent Device

FIG. 4 is a diagram of a white light luminescent device according to an embodiment of the present invention. Referring to FIG. 4, a white light luminescent device 200 includes an LED chip 210 and a photo-luminescent fluorescence body 220. The LED chip 210 emits a first light L1 and the photo-luminescent fluorescence body 220 includes at least the above-mentioned red-light-emitting fluorescent material. The photo-luminescent fluorescence body 220 is excited by the first light L1 to emit a second light L2. The first light L1 and the second light L2 then are mixed into white light.

The wavelengths of the first light L1 may range between 360 nm˜550 nm. When the wavelength range of the first light L1 is the wavelengths of near-ultraviolet radiation 394±10 nm, the wavelengths of blue light 465±10 nm or the wavelengths of yellow-green light 535±10 nm, the first light L1 can better excite the photo-luminescent fluorescence body 220 (at least containing the above-mentioned red-light-emitting fluorescent material) so that the photo-luminescent fluorescence body 220 emits the second light L2.

In addition, the above-mentioned photo-luminescent fluorescence body 220 can further include yellow-light-emitting fluorescent material (not shown), blue-light-emitting fluorescent material (not shown) or green-light-emitting fluorescent material (not shown). The above-mentioned red-light-emitting fluorescent material is suitable for applications in coordination with the yellow-light-emitting fluorescent material, the blue-light-emitting fluorescent material, the green-light-emitting fluorescent material and combination thereof.

In more details, in the white light luminescent device 200, the photo-luminescent fluorescence body 220 can be solely the red-light-emitting fluorescent material of the present invention, or a dual-phosphor composition system, or even a multiple-phosphor composition system. For example, when the photo-luminescent fluorescence body 220 is solely the red-light-emitting fluorescent material provided by the present invention, the LED chip 210 can choose, for example, a blue-green LED. Meanwhile, the first light L1 (blue-green light) emitted by the LED chip 210 and the second light L2 (red light) emitted by the red-light-emitting fluorescent material are mixed into white light.

When the photo-luminescent fluorescence body 220 is a dual-phosphor composition system, the photo-luminescent fluorescence body 220 can be, for example, a mixture of the red-light-emitting fluorescent material provided by the present invention and another yellow-light-emitting fluorescent material. At the time, the LED chip 210 can choose, for example, a blue LED for emitting the first light L1 (blue light), while the second light L2 is the blended light of red light and yellow light. After the first light L1 and the second light L2 are mixed, the white light is produced.

Meanwhile, the photo-luminescent fluorescence body 220 can be a mixture of the red-light-emitting fluorescent material provided by the present invention, the green-light-emitting fluorescent material and the blue-light-emitting fluorescent material. At the time, the LED chip 210 can choose, for example, a ultraviolet radiation LED for emitting the first light L1 (ultraviolet radiation light), while the second light L2 produced by the photo-luminescent fluorescence body 220 is the blended light of blue light, green light and red light. After, the blended light of blue light, green light and red light is further mixed with ultraviolet radiation so as to provide white light.

It can be seen from the described above, the white light luminescent device 200 can be implemented by using different phosphor composition system, the different LEDs and the different combinations thereof for producing white light. Anyone skilled in the art can adjust the combinations according to the application practice.

In summary, the red light fluorescent material, the manufacturing method thereof, and the white light emitting device have at least following advantages.

The red-light-emitting fluorescent material has a unique crystal structure and is able to produce red light with high color purity and high luminance so as to enhance the color rendering of white light. In addition, since the red-light-emitting fluorescent material of the present invention is oxide, in comparison with the conventional fluorescent powder containing sulfide, the present invention has good chemical stability (moisture-proof and heat-resistant). Moreover, in the manufacturing method of the red-light-emitting fluorescent material provided by the present invention, the required sintering temperature is lower, which is advantageous in less energy consumption. And, white light luminescent devices employing the above-mentioned red-light-emitting fluorescent material is advantageous in long lifetime and more broad applications.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A red-light-emitting fluorescent material, suitable for being excited by a first light to emit a red light, the red-light-emitting fluorescent material comprising following chemical formula (1):
A₃B₂C₃(MO₄)₈:Eu³⁺ (1)
wherein,
A represents Li, Na, K, Rb, Cs or Ag;
B represents Mg, Ca, Sr or Ba;
C represents Y, Gd or La; and
M represents Mo, W or the combination of Mo and W (MoₓW₍₁₋ₓ₎).

2. The red-light-emitting fluorescent material as claimed in claim 1, wherein the wavelength ranges of the first light is between 360 nm˜550 nm.

3. The red-light-emitting fluorescent material as claimed in claim 1, wherein the wavelength ranges of the first light comprise:
wavelength range of near-ultraviolet radiation 394±10 nm, wavelength range of blue light 465±10 nm; or
wavelength range of yellow-green light 535±10 nm.

4. The red-light-emitting fluorescent material as claimed in claim 1, wherein the wavelength of the red light comprises 614 nm.

5. The red-light-emitting fluorescent material as claimed in claim 1, wherein in the M expression of combination of Mo and W (MoₓW₍₁₋ₓ₎), x is mole fraction and x is between 0˜1.

6. The red-light-emitting fluorescent material as claimed in claim 1, wherein a color coordinates of the red light reach (0.66, 0.33).

7. The red-light-emitting fluorescent material as claimed in claim 1, wherein a relative luminance of the red light is 1.5˜1.8 (cd/m²).

8. The red-light-emitting fluorescent material as claimed in claim 1, wherein the red-light-emitting fluorescent material is suitable for being used in a white light emitting diode.

9. A manufacturing method of red-light-emitting fluorescent material, comprising:
providing a mixture as per chemical dose, wherein the mixture comprises a metal carbonate, an alkaline-earth-metal carbonate, a trivalent metal oxide, a rare earth oxide, and a molybdenum trioxide, or a tungsten trioxide or a combination of molybdenum trioxide and tungsten trioxide;
mixing up and grinding the mixture; and
sintering the mixture after being mixed and grinded, so as to form the red-light-emitting florescent material.

10. The manufacturing method of red-light-emitting fluorescent material as claimed in claim 9, further comprising:
providing a halogenated ammonium salt as flux, wherein the weight percent of the halogenated ammonium salt is 10 wt %.

11. The manufacturing method of red-light-emitting fluorescent material as claimed in claim 9, wherein the time for mixing and grinding the mixture is 30 min.

12. The manufacturing method of red-light-emitting fluorescent material as claimed in claim 9, wherein the sintering temperature of the mixture is 600° C.˜800° C.

13. The manufacturing method of red-light-emitting fluorescent material as claimed in claim 9, wherein the sintering time of the mixture is between 6˜10 hours.

14. The manufacturing method of red-light-emitting fluorescent material as claimed in claim 9, wherein the red-light-emitting fluorescent material has following chemical formula (1):
A₃B₂C₃(MO₄)₈:Eu³⁺ (1)
wherein,
A represents Li, Na, K, Rb, Cs or Ag;
B represents Mg, Ca, Sr or Ba;
C represents Y, Gd or La; and
M represents Mo, W or combination of Mo and W (MoₓW₍₁₋ₓ₎).

15. The manufacturing method of red-light-emitting fluorescent material as claimed in claim 9, further comprising:
a characteristics identification step for identifying physical and chemical characteristics of the red-light-emitting florescent material.

16. The manufacturing method of red-light-emitting fluorescent material as claimed in claim 15, wherein the characteristics identification step comprises:
X-radiation diffraction analysis, photoluminescence (PL) spectroscopic analysis, chromaticity coordinate analysis or ultraviolet radiation-visual light reflection spectrum analysis.

17. A white light luminescent device, comprising:
a light-emitting-diode chip for emitting a first light; and
a photo-luminescent fluorescence body, comprising at least the red-light-emitting fluorescent material as claimed in claim 1;
wherein, the photo-luminescent fluorescence body is excited by the first light to emit a second light, and the first light and the second light are mixed into white light.

18. The white light luminescent device as claimed in claim 17, wherein the wavelength ranges of the first light is between 360 nm˜550 nm.

19. The white light luminescent device as claimed in claim 17, wherein the wavelength range of the first light comprises:
wavelength range of near-ultraviolet radiation 394±10 nm,
wavelength range of blue light 465±10 nm; or
wavelength range of yellow-green light 535±10 nm.

20. The white light luminescent device as claimed in claim 17, wherein the photo-luminescent fluorescence body further comprises:
a yellow-light-emitting fluorescent material, a blue-light-emitting fluorescent material or a green-light-emitting fluorescent material;
wherein, the red-light-emitting fluorescent material is suitable for application in coordination with the yellow-light-emitting fluorescent material, a blue-light-emitting fluorescent material, a green-light-emitting fluorescent material and a combination thereof.
